(19) United States
(12) Patent Application Publication
(10) Pub. No.: US 2026/0151847 A1
(43) Pub. Date: Jun. 4, 2026

(54) BONDING HEAD AND SEMICONDUCTOR CHIP BONDING APPARATUS INCLUDING THE SAME

(71) Applicant: Samsung Electronics Co., Ltd., Suwon-si (KR)

(72) Inventors: Sungjin Han, Suwon-si (KR); Kwangbae Kim, Suwon-si (KR); Soohwan Lee, Suwon-si (KR); Jingyu Shin, Suwon-si (KR); Hyunchul Jung, Suwon-si (KR); Youngkun Jee, Suwon-si (KR)

(21) Appl. No.: 19/289,627

(22) Filed: Aug. 4, 2025

(30) Foreign Application Priority Data
Dec. 4, 2024 (KR) 10-2024-0178858

(51) Int. Cl. H01L 23/00; B23K 20/02; B23K 101/40

(52) U.S. Cl. CPC B23K 20/02; B23K 2101/40; H10W 72/071

(57) ABSTRACT

An example of a bonding head includes a head body, a collet detachably attached to a lower surface of the head body, the collet including a metal plate and a deformation plate on a lower surface of the metal plate, wherein the collet further includes an aperture and a plurality of vacuum lines, wherein the aperture passes through the metal plate and a portion of the deformation plate, the plurality of vacuum lines pass through the metal plate and the deformation plate, the deformation plate of the collet includes a protrusion protruding in a vertical direction from a lower surface of the deformation plate, and a lower surface of the protrusion of the deformation plate of the collet includes a first area that is a curved surface being convex outward.

### CROSS-REFERENCE TO RELATED APPLICATION(S)

This application is based on and claims priority under 35 U.S.C. § 119 to Korean Patent Application No. 10-2024-0178858, filed on Dec. 4, 2024, in the Korean Intellectual Property Office, the disclosure of which is incorporated by reference herein in its entirety.

### BACKGROUND

As semiconductor chips continue to be highly integrated, the importance of a bonding process for stacking chips has gradually increased. Particularly, research and development has been actively conducted on hybrid copper bonding (HCB). HCB is used to maintain bonding between semiconductor chips and improve electrical and mechanical characteristics.

### SUMMARY

In an HCB process, it is desired that pressure applied to a semiconductor chip has uniform coverage. When the pressure does not have uniform coverage, degradation in the quality of bonding may occur and cause degradation in performance or issues with reliability of a semiconductor device.

The present disclosure provides a bonding head, which has a uniform coverage in an external force applied to semiconductor chips being stacked, and a semiconductor chip bonding apparatus including the bonding head.

However, the objectives to be achieved by the present disclosure are not limited thereto, and other unmentioned objectives may be clearly understood by those skilled in the art from the following descriptions.

According to an aspect of the present disclosure, a bonding head includes a head body, a collet detachably attached to a lower surface of the head body, the collet including a metal plate and a deformation plate on a lower surface of the metal plate, wherein the collet further includes an aperture and a plurality of vacuum lines, wherein the aperture passes through the metal plate and a portion of the deformation plate, the plurality of vacuum lines pass through the metal plate and the deformation plate, the deformation plate of the collet includes a protrusion protruding in a vertical direction from a lower surface of the deformation plate, and a lower surface of the protrusion of the deformation plate of the collet includes a first area that is a curved surface being convex outward.

According to another aspect of the present disclosure, a semiconductor chip bonding apparatus includes a bonding head including a head body and a collet, wherein the collet is attached to a lower surface of the head body and includes a metal plate and a deformation plate, a vacuum pump connected to the head body of the bonding head, and a pressurizer connected to the head body of the bonding head, wherein the collet of the bonding head further includes an aperture passing through the metal plate and a portion of the deformation plate and a plurality of vacuum lines passing through the metal plate and the deformation plate, wherein the deformation plate of the collet includes a protrusion protruding in a vertical direction from a lower surface of the deformation plate, a lower surface of the protrusion of the deformation plate of the collet includes a first area that is a curved surface being convex outward, and the aperture of the collet and each of the plurality of vacuum lines of the collet vertically overlap the protrusion of the deformation plate of the collet.

According to another aspect of the present disclosure, a semiconductor chip bonding apparatus includes a bonding head including a head body and a collet, wherein the head body includes a plurality of first through-holes and a second through-hole, the collet is attached to a lower surface of the head body and includes a metal plate and a deformation plate, a vacuum pump connected to the plurality of first through-holes of the head body of the bonding head, wherein the collet of the bonding head further includes an aperture communicating with the second through-hole of the head body, completely passing through the metal plate, and passing through at least a portion of the deformation plate, and a plurality of vacuum lines respectively communicating with the plurality of first through-holes of the head body and completely passing through the metal plate and the deformation plate, wherein the deformation plate of the collet includes a protrusion protruding in a vertical direction from a lower surface of the deformation plate, a lower surface of the protrusion of the deformation plate of the collet includes a first area that is a curved surface being convex outward, and the aperture of the collet and each of the plurality of vacuum lines of the collet vertically overlap the protrusion of the deformation plate of the collet.

### BRIEF DESCRIPTION OF THE DRAWINGS

Implementations will be more clearly understood from the following detailed description taken in conjunction with the accompanying drawings in which:

FIG. 1 is a cross-sectional view schematically illustrating a bonding head according to an implementation;

FIG. 2 is a plan view schematically illustrating a collet according to an implementation;

FIG. 3 is a cross-sectional view schematically illustrating a cross-section of the collet shown in FIG. 2, taken along a line A1-A1′ in FIG. 2;

FIG. 4 is an enlarged view schematically illustrating a portion EX of the collet of FIG. 3;

FIG. 5 is a plan view schematically illustrating a collet according to an implementation;

FIG. 6 is a cross-sectional view schematically illustrating a cross-section of the collet shown in FIG. 5, taken along a line A2-A2′ in FIG. 5;

FIG. 7 is a plan view schematically illustrating a collet according to an implementation;

FIG. 8 is a cross-sectional view schematically illustrating a cross-section of the collet in FIG. 7, taken along a line A3-A3′ in FIG. 7;

FIG. 9 is a plan view schematically illustrating a collet according to an implementation;

FIGS. 10 and 11 are configuration diagrams schematically illustrating a semiconductor chip bonding apparatus according to an implementation;

FIGS. 12 and 13 are configuration diagrams schematically illustrating a semiconductor chip bonding apparatus according to an implementation; and

FIGS. 14A to 14F are configuration diagrams sequentially illustrating processes of bonding semiconductor chips performed by a semiconductor chip bonding apparatus according to an implementation.

### DETAILED DESCRIPTION

Implementations are provided to more fully describe the present disclosure to those skilled

in the art. The following implementations may be modified various types of different forms, and the scope of the present disclosure is not limited to the following implementations. Rather, the implementations are provided to more fully and thoroughly describe the present disclosure and thoroughly deliver the present disclosure to those skilled in the art.

In the present specification, space-relative terms such as “top surfaces,” “lower surfaces,” “on,” “under,” “above,” and “below” are used to easily describe position relationships among components with reference to directions shown in the drawings. Therefore, seen in a direction different from the directions shown in the drawings, the space-relative terms indicating the position relationships among the components may be differently understood.

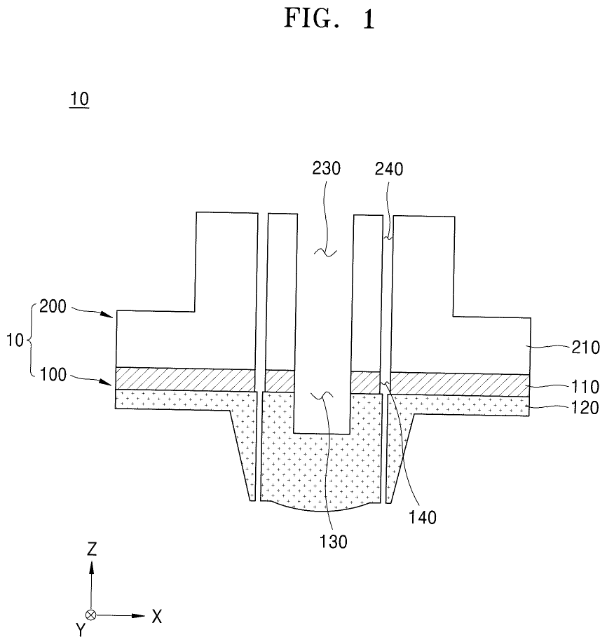

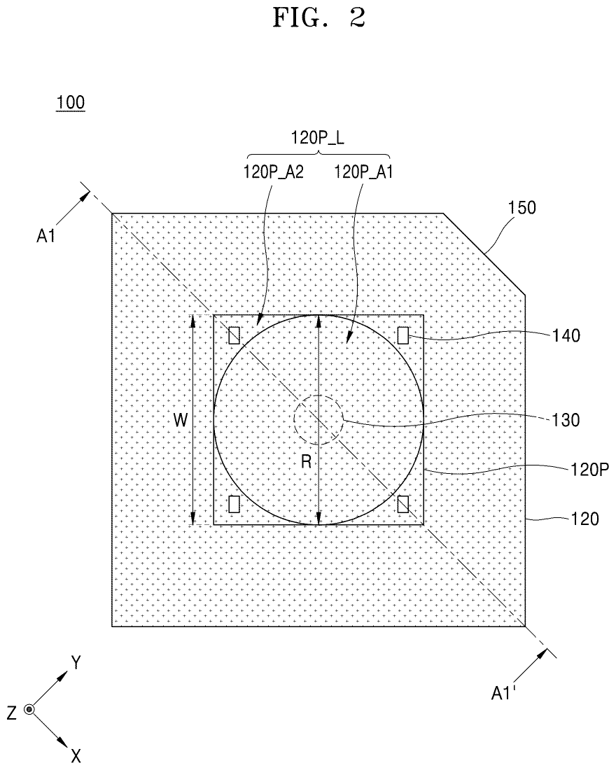

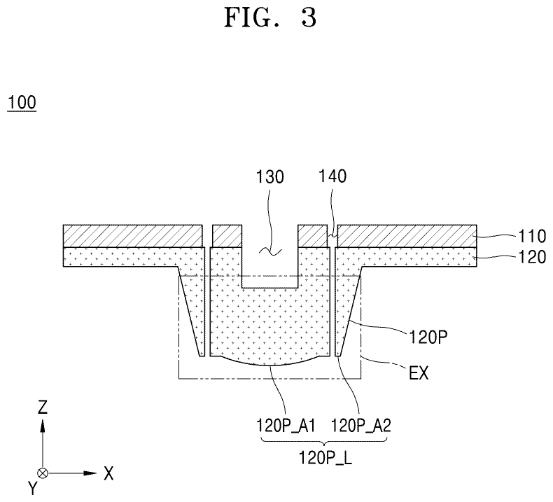

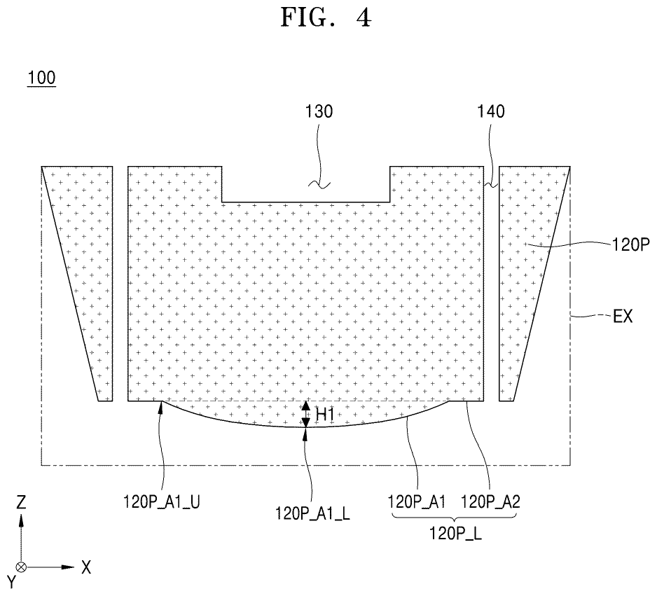

FIG. 1 is a cross-sectional view schematically illustrating a bonding head 10 according to an implementation. FIG. 2 is a plan view schematically illustrating a collet 100 according to an implementation. FIG. 3 is a cross-sectional view schematically illustrating a cross-section of the collet 100 shown in FIG. 2, taken along a line A1-A1′ in FIG. 2. FIG. 4 is an enlarged view schematically illustrating an image of a portion EX of the collet 100, which is shown in FIG. 3.

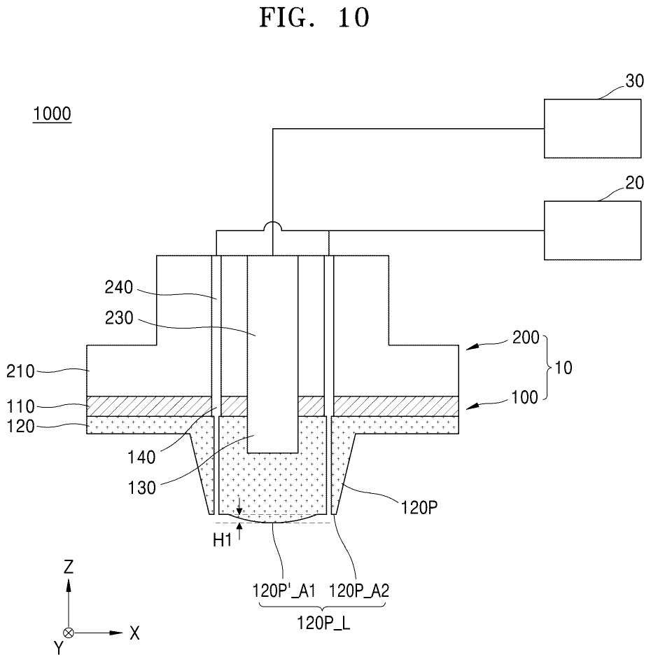

Referring to FIGS. 1 to 4, the bonding head 10 may include a head body 200 and the collet 100. The bonding head 10, which is a component included in a semiconductor chip bonding apparatus 1000 (see FIG. 10), may move the head body 200 in a first horizontal direction (a X direction), a second horizontal direction (a Y direction), and a vertical direction (a Z direction). As the head body 200 is moved, the collet 100 attached to the head body 200 may be moved along the head body 200.

In the present specification, unless particularly defined, a direction parallel to a top surface of the collet 100 will be defined as the first horizontal direction (the X direction), a direction perpendicular to the top surface of the collet 100 will be defined as the vertical direction (the Z direction), and a direction perpendicular to the first horizontal direction (the X direction) and the vertical direction (the Z direction) will be defined as the second horizontal direction (the Y direction). A horizontal direction will be defined as a direction that is a combination of the first horizontal direction (the X direction) and the second horizontal direction (the Y direction).

The bonding head 10 may be configured such that the collet 100 is attached to the bonding head 10. For example, the collet 100 may be detachably attached to the bonding head 10. For example, the collet 100 attached to the bonding head 10 may be replaced according to bonding environments. For example, the collet 100 may be attached to a lower surface of the bonding head 10 through a clamping method. However, the implementation is not limited thereto, and the collet 100 may be attached to the lower surface of the bonding head 10 through an interference fit method or a screw fixing method.

The bonding head 10 will be further described below.

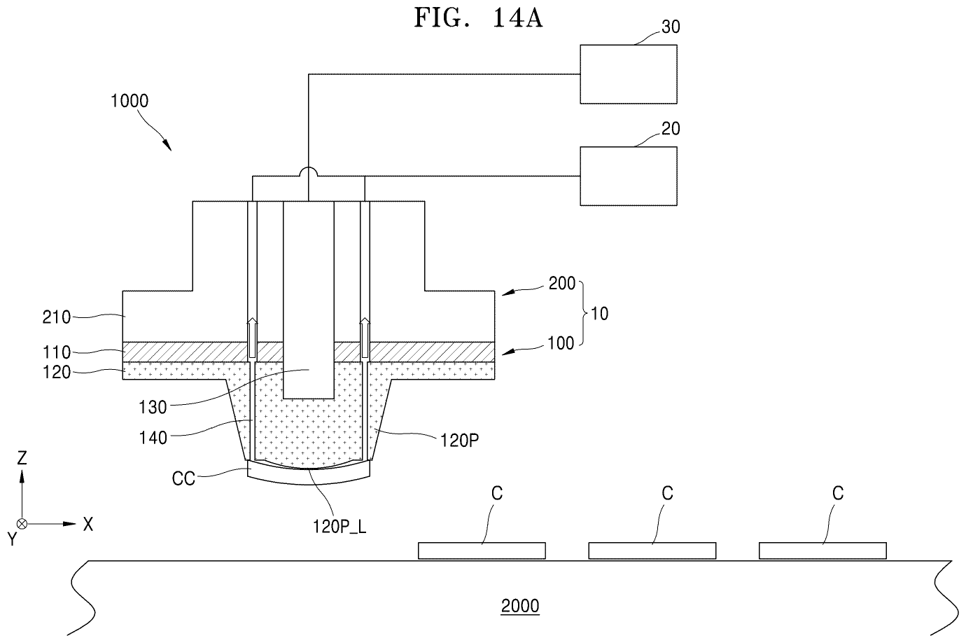

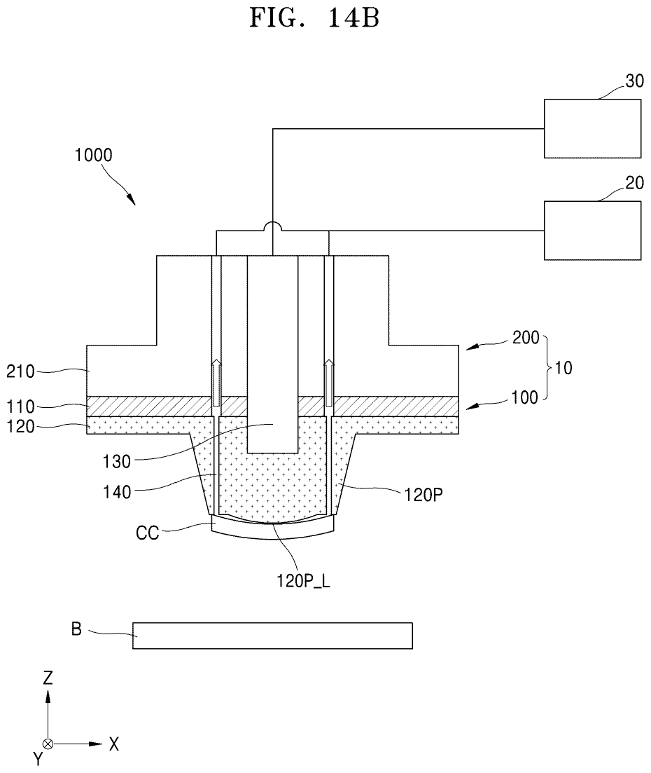

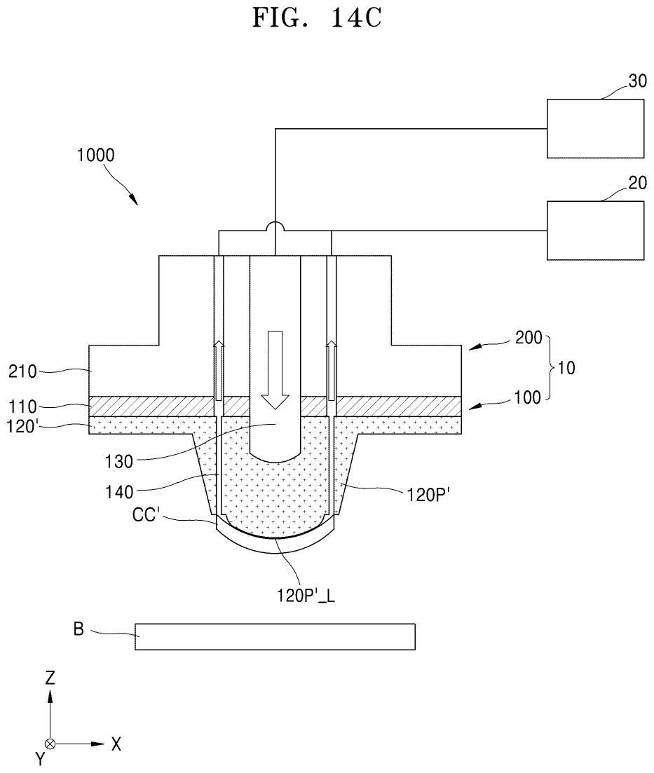

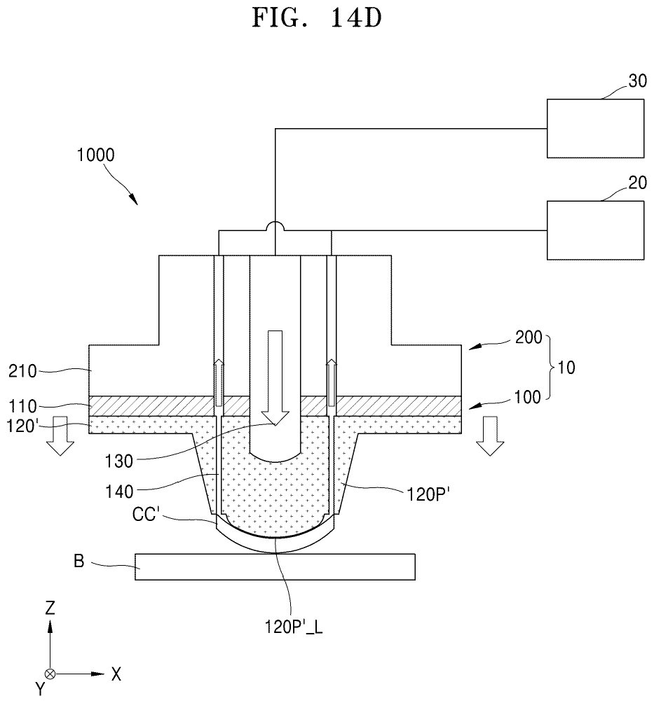

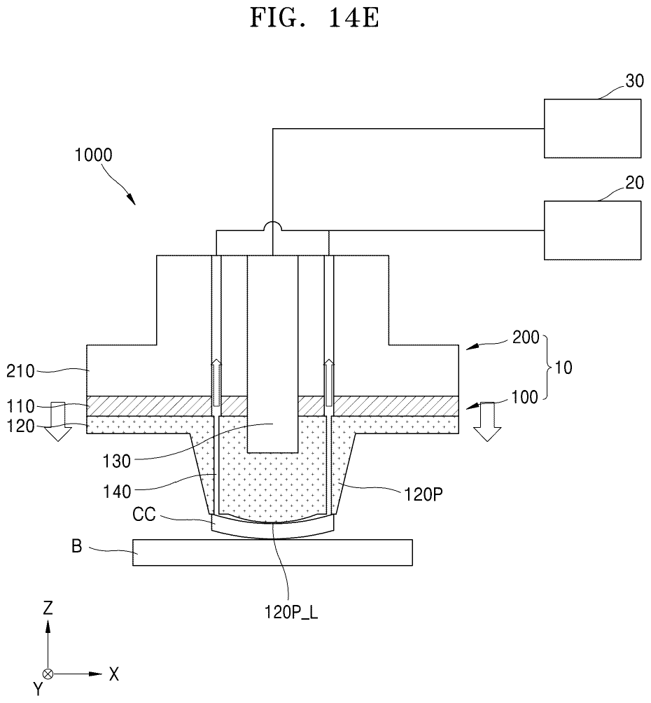

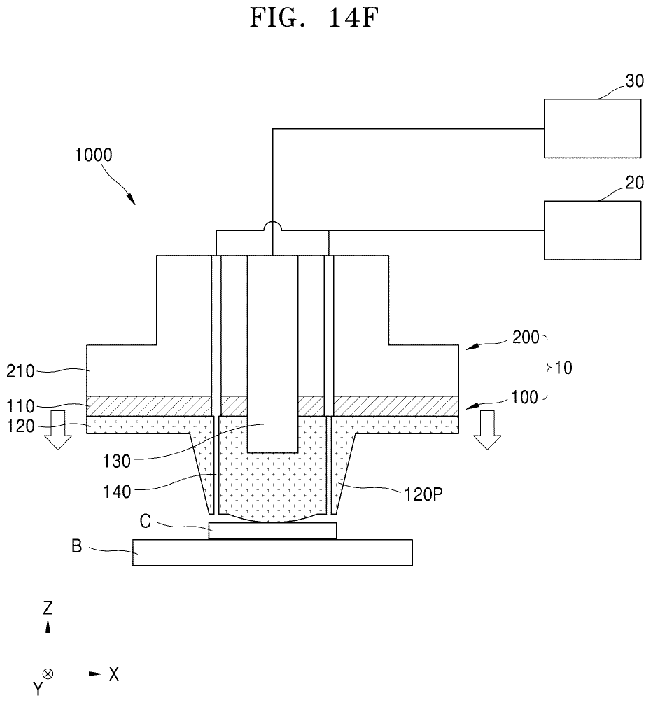

The collet 100 may include a metal plate 110 and a deformation plate 120 on a bottom surface of the metal plate 110. For example, the metal plate 110 may include a portion combined to the head body 200, and the deformation plate 120 may include a portion brought into contact with a first semiconductor chip C (see FIG. 14A). For example, the deformation plate 120 may be apart from the head body 200 with the metal plate 110 therebetween.

For example, an elastic modulus of the metal plate 110 may be greater than an elastic modulus of the deformation plate 120. The elastic modulus of the deformation plate 120 may be about 3 MPa to about 5 MPa. For example, even when the deformation plate 120 is deformed due to an external force, the deformation plate 120 may return to the initial shape upon release from the external force.

The deformation plate 120 of the collet 100 may further include a protrusion 120P. The protrusion 120P may protrude in the vertical direction (the Z direction) from a bottom surface of the deformation plate 120. For example, referring to FIG. 1, the protrusion 120P may protrude downward in the vertical direction (the Z direction) from the bottom surface of the deformation plate 120. In some implementations, the protrusion 120P may have a tapered shape of which a width decreases away from the bottom surface of the deformation plate 120.

In some implementations, a length of the metal plate 110 in the vertical direction (the Z direction), i.e., the thickness of the metal plate 110, may be about 1 mm to about 2 mm. For example, the metal plate 110 may have the form of a flat plate. In a portion of the deformation plate 120, except the protrusion 120P, a thickness of the deformation plate 120 may be about 0.5 mm to about 1.5 mm. For example, in a portion of the deformation plate 120, which does not include the protrusion 120P, a length from a top surface of the deformation plate 120 to the bottom surface of the deformation plate 120 may be about 0.5 mm to about 1.5 mm. A thickness of the protrusion 120P in the deformation plate 120 may be about 2.5 mm to about 4.5 mm. For example, a length from the bottom surface of the metal plate 110 to a bottom surface 120P_L of the protrusion 120P may be about 2.5 mm to about 4.5 mm.

The lower surface 120P_L of the protrusion 120P of the deformation plate 120 may include a curved surface being convex outward. For example, the lower surface 120P_L of the protrusion 120P may have a dome shape being convex outward. In the lower surface 120P_L of the protrusion 120P, a portion that is the curved surface being convex outward may be referred to as a first area 120P_A1.

The lower surface 120P_L of the protrusion 120P of the deformation plate 120 may be divided into the first area 120P_A1 and a second area 120P_A2. The first area 120P_A1 of the lower surface 120P_L of the protrusion 120P may include a curved surface, and the second area 120P_A2 of the lower surface 120P_L of the protrusion 120P may include a plane surrounding the first area 120P_A1. For example, in the lower surface 120P_L of the protrusion 120P, a portion without a curvature may be referred to as the second area 120P_A2.

In some implementations, the first area 120P_A1 of the lower surface 120P_L of the protrusion 120P may be in a center area of the lower surface 120P_L of the protrusion 120P. The second area 120P_A2 of the lower surface 120P_L of the protrusion 120P may be in a corner area of the lower surface 120P_L of the protrusion 120P. For example, the corner area of the lower surface 120P_L of the protrusion 120P may include an area adjacent to a vertex of the lower surface 120P_L of the protrusion 120P.

In some implementations, the first area 120P_A1 of the lower surface 120P_L of the protrusion 120P is a curved surface being convex downward in the vertical direction (the Z direction). In the first area 120P_A1, a point having a lowest vertical level may be referred to as a lowermost end 120P_A1_L of the first area 120P_A1, and a point having a highest vertical level may be referred to as an uppermost end 120P_A1_U of the first area 120P_A1. For example, the uppermost end 120P_A1_U of the first area 120P_A1 may be a point being in contact with the second area 120P_A2 of the lower surface 120P_L of the protrusion 120P.

For example, in a plan view, the lower surface 120P_L of the protrusion 120P may have a square shape having a width W as a first length. In a plan view, the first area 120P_A1 of the lower surface 120P_L of the protrusion 120P may have a circular shape having a diameter R as the first length. For example, the diameter R of the first area 120P_A1 of the lower surface 120P_L of the protrusion 120P may be equal to the width of the lower surface 120P_L of the protrusion 120P. In the present specification, the plan view may indicate a view of observing a X-Y plane through projection in a Z axis direction.

In some implementations, and in a plan view, the lower surface 120P_L of the protrusion 120P may have a rectangular shape in which a vertical length is different from a horizontal length. The diameter R of the first area 120P_A1 of the lower surface 120P_L of the protrusion 120P may be identical to a smaller length between the vertical length and the horizontal length of the lower surface 120P_L of the protrusion 120P.

In some implementations, a distance H1 in the vertical direction (the Z direction) between the uppermost end 120P_A1_U of the first area 120P_A1 and the lowermost end 120P_A1_L of the first area 120P_A1 may be about 30 μm to about 80 μm. In some implementations, the width W of the lower surface 120P_L of the protrusion 120P may be about 9 mm to about 12 mm. In some implementations, a curvature of the first area 120P_A1 of the lower surface 120P_L of the protrusion 120P may be about 0.002 mm⁻¹ to about 0.005 mm⁻¹.

The collet 100 may further include an aperture 130 and a plurality of vacuum lines 140. The aperture 130 may completely penetrate the metal plate 110 and penetrate a portion of the deformation plate 120. Each of the plurality of vacuum lines 140 may completely penetrate the metal plate 110 and the deformation plate 120.

In some implementations, the aperture 130 may overlap the first area 120P_A1 of the lower surface 120P_L of the protrusion 120P of the deformation plate 120 of the collet 100 in the vertical direction (the Z direction). Each of the plurality of vacuum lines 140 may overlap the second area 120P_A2 of the lower surface 120P_L of the protrusion 120P of the deformation plate 120 in the vertical direction (the Z direction).

For example, the aperture 130 may overlap the lowermost end 120P_A1_L of the first area 120P_A1 of the lower surface 120P_L of the protrusion 120P in the vertical direction (the Z direction). In the protrusion 120P of the deformation plate 120, a portion overlapping the aperture 130 of the collet 100 may have a shape being convex outward. In some implementations, the aperture 130 may overlap the center area of the lower surface 120P_L of the protrusion 120P in the vertical direction (the Z direction).

The thickness of the deformation plate 120 may be compensated for by the first area 120P_A1 of the lower surface 120P_L of the protrusion 120P, which is under the aperture 130 and convex outward. In a process of bonding the first semiconductor chip C (see FIG. 14) onto a second semiconductor chip B (see FIG. 14B), the degree to which the deformation plate 120 is deformed and causes a decrease in volume of the aperture 130 may be reduced. Accordingly, a pressure applied to a center area of the first semiconductor chip C may relatively increase, and the reliability of combination between the first semiconductor chip C and the second semiconductor chip B may be improved.

In some implementations, each of the plurality of vacuum lines 140 may include an upper vacuum line and a lower vacuum line. The upper vacuum line may be in the metal plate 110 and have a first width. The lower vacuum line may be in the deformation plate 120 and have a second width. The upper vacuum line and the lower vacuum line may communicate with each other. The second width may be smaller than the first width.

In some implementations, the aperture 130 may include an upper aperture and a lower aperture. The upper aperture may be in the metal plate 110, and the lower aperture may be in the deformation plate 120. For example, a diameter of the upper aperture and a diameter of the lower aperture may be identical to each other.

In some implementations, the diameter of the aperture 130 may be different from the width of each of the plurality of vacuum lines 140. For example, the diameter of the aperture 130 may be greater than the width of each of the plurality of vacuum lines 140. For example, a diameter of the aperture 130 may be about 4 mm to about 7 mm. The width of each of the plurality of vacuum lines 140 may be about 0.5 mm to about 1 mm.

In FIG. 2, a cross-section of the aperture 130 is illustrated as a circular shape, but the implementation is not limited thereto, and the cross-section of the aperture 130 may have a polygonal shape.

In FIG. 2, a cross-section of each of the plurality of vacuum lines 140 is illustrated as a square shape, but the implementation is not limited thereto, and the cross-section of each of the plurality of vacuum lines 140 may have a circular shape or a polygonal shape.

The collet 100 may further include a batch guide portion 150. The batch guide portion 150 may include a notch portion. In a plan view, two end portions of the notch portion may be connected to two neighboring side surfaces of the collet 100, respectively.

For example, the notch portion may be formed by removing a corner portion of the collet 100. Here, the corner portion of the collet 100 may include a portion at which the two neighboring side surfaces of the collet 100 meet each other. In a process of bonding semiconductor chips, the batch guide portion 150 may provide information about positions or directions of the bonding head 10. Alternatively, the batch guide portion 150 may include a marking or a stamping formed on the collet 100.

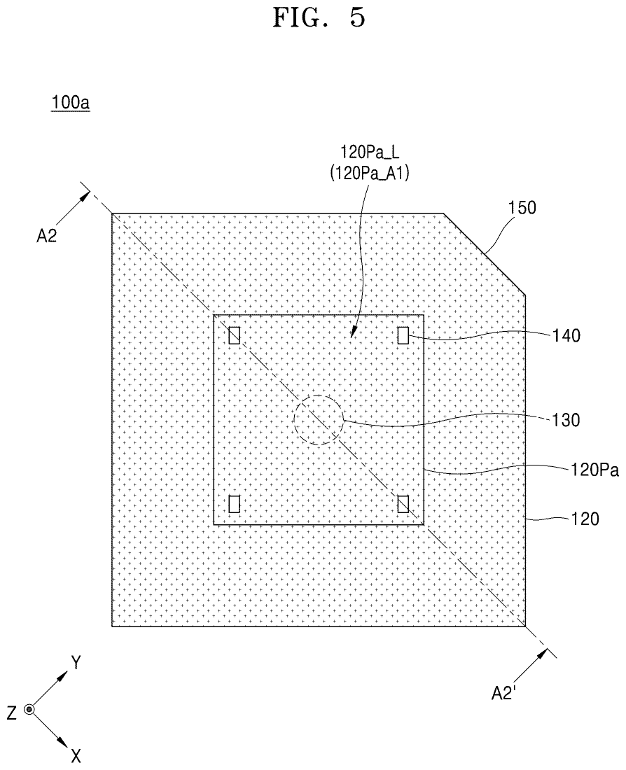

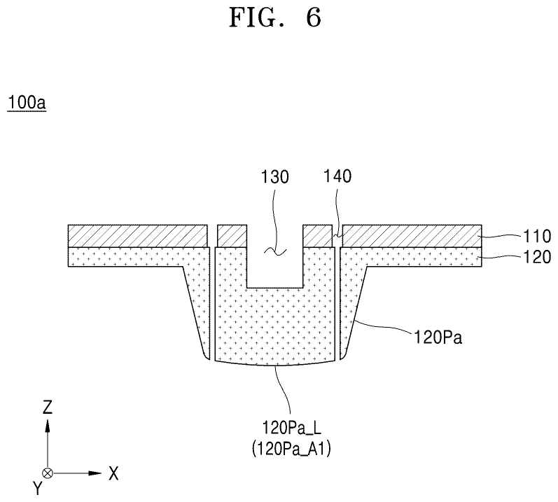

FIG. 5 is a plan view schematically illustrating a collet 100a according to an implementation. FIG. 6 is a cross-sectional view schematically illustrating a cross-section of the collet 100a shown in FIG. 5, taken along a line A2-A2′ in FIG. 5.

Most of components included in the collet 100a or materials included in the components, which will be described below, are substantially identical or similar to the components or materials described above. Therefore, for convenience of description, differences between the collet 100a in FIG. 5 and the collet 100 in FIG. 2 described above will be mainly described.

Referring to FIGS. 5 and 6, the collet 100a may include the metal plate 110 and the deformation plate 120 on the lower surface of the metal plate 110. For example, the metal plate 110 may have the form of a flat plate, and the deformation plate 120 may include a protrusion 120Pa on the lower surface. The protrusion 120Pa of the deformation plate 120 may include a portion protruding downward in the vertical direction (the Z direction) from the lower surface of the deformation plate 120. For example, although a position of the deformation plate 120 and a direction in which the protrusion 120Pa of the deformation plate 120 protrudes have been described with reference to FIG. 6, but the position of the deformation plate 120 and the direction in which the protrusion 120Pa protrudes may differ according to directions in which the collet 100 a is arranged.

In some implementations, the elastic modulus of the metal plate 110 may be greater than the elastic modulus of the deformation plate 120. For example, when a same pressure is applied to the deformation plate 120 and the metal plate 110, the deformation plate 120 may be deformed by a greater degree compared with the metal plate 110.

A lower surface 120Pa_L of the protrusion 120Pa may include a curved surface being convex outward. For example, the lower surface 120Pa_L of the protrusion 120Pa of the deformation plate 120 may be closer to the upper surface of the deformation plate 120 away from a center of the lower surface 120Pa_L. For example, when a portion having a curvature in the lower surface 120Pa_L of the protrusion 120Pa of the deformation plate 120 is referred to as a first area 120Pa_A1, the entire portion of the lower surface 120Pa_L of the protrusion 120Pa of the deformation plate 120 may be included in the first area 120Pa_A1. For example, an area of the lower surface 120Pa_L of the protrusion 120Pa of the deformation plate 120 and an area of the first area 120Pa_A1 may be identical to each other. For example, the first area 120Pa_A1 of the lower surface 120Pa_L of the protrusion 120Pa of the deformation plate 120 may be in contact with a side surface of the protrusion 120Pa of the deformation plate 120.

The collet 100a may further include the aperture 130 and the plurality of vacuum lines 140. The aperture 130 may penetrate the metal plate 110 and penetrate a portion of the deformation plate 120. The plurality of vacuum lines 140 may penetrate the metal plate 110 and the deformation plate 120. A length of the aperture 130 in the vertical direction (the Z direction) may be less than the length of each of the plurality of vacuum lines 140 in the vertical direction (the Z direction).

Each of the plurality of vacuum lines 140 and the aperture 130 may be apart from each other in the horizontal directions. Fluid in each of the plurality of vacuum lines 140 and the aperture 130 may be separated. For example, each of the plurality of vacuum lines 140 and the aperture 130 may not communicate with each other.

For example, the plurality of vacuum lines 140 may be adjacent to a vertex of the lower surface 120Pa_L of the protrusion 120Pa of the deformation plate 120, and the aperture 130 may be adjacent to a center of the lower surface 120Pa_L of the protrusion 120Pa of the deformation plate 120. For example, the aperture 130 may overlap a lowermost end of the lower surface 120Pa_L of the protrusion 120Pa of the deformation plate 120 in the vertical direction (the Z direction).

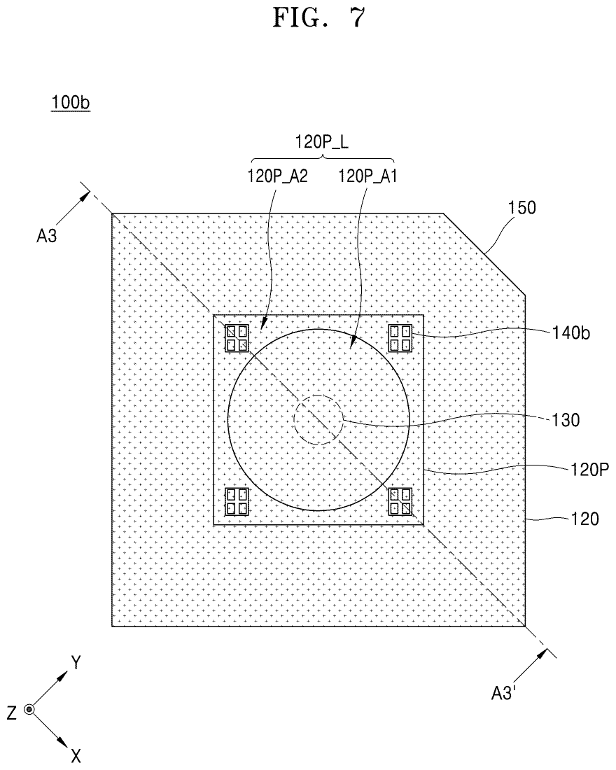

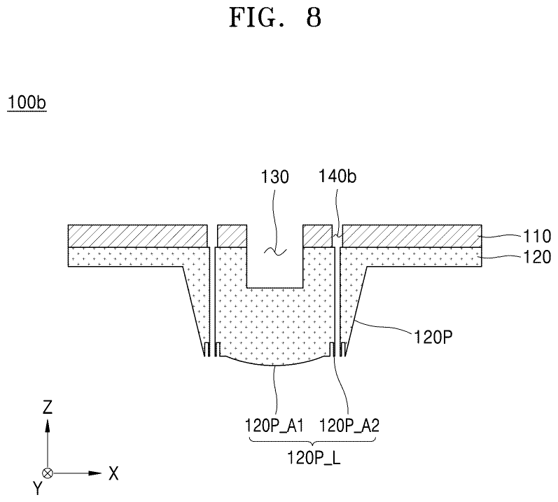

FIG. 7 is a plan view schematically illustrating a collet 100b according to an implementation. FIG. 8 is a cross-sectional view schematically illustrating a cross-section of the collet 100b shown in FIG. 7, which is taken along a line A3-A3′ in FIG. 5.

Most of components included in the collet 100b or materials included in the components, which will be described below, are substantially identical or similar to the components or materials described above. Therefore, for convenience of description, differences between the collet 100b in FIG. 7 and the collet 100 in FIG. 2 described above will be mainly described.

Referring to FIGS. 7 and 8, the collet 100b may include the metal plate 110 and the deformation plate 120 on the lower surface of the metal plate 110. The deformation plate 120 may further include the protrusion 120P protruding outward from the lower surface of the deformation plate 120.

The lower surface 120P_L of the protrusion 120P of the deformation plate 120 may be divided into the first area 120P_A1 and the second area 120P_A2 surrounding the first area 120P_A1. The first area 120P_A1 of the lower surface 120P_L of the protrusion 120P of the deformation plate 120 may include a curved surface being convex outward. The second area 120P_A2 of the lower surface 120P_L of the protrusion 120P of the deformation plate 120 may include a plane. In a plan view, the first area 120P_A1 of the lower surface 120P_L of the protrusion 120P may have a circular shape, and the lower surface 120P_L of the protrusion 120P may have a square shape.

The collet 100b may further include the aperture 130 and a plurality of vacuum lines 140b. The aperture 130 may penetrate the metal plate 110 and penetrate a portion of the deformation plate 120. Each of the plurality of vacuum lines 140b may completely penetrate the metal plate 110 and the deformation plate 120. For example, the length of the aperture 130 in the vertical direction (the Z direction) may be less than a length of each of the plurality of vacuum lines 140b in the vertical direction (the Z direction). For example, the diameter of the aperture 130 may be greater than a width of each of the plurality of vacuum lines 140b.

In some implementations, the aperture 130 may overlap the first area 120P_A1 of the lower surface 120P_L of the protrusion 120P of the deformation plate 120 in the vertical direction (the Z direction), and the plurality of vacuum lines 140b may overlap the second area 120P_A2 of the lower surface 120P_L of the protrusion 120P of the deformation plate 120 in the vertical direction (the Z direction).

Each of the plurality of vacuum lines 140b may branch out into a plurality of lines at an end portion adjacent to the lower surface of the protrusion 120P of the deformation plate 120. For example, each of the plurality of vacuum lines 140b may have the form in which a line branches out into a plurality of lines.

For example, each of the plurality of vacuum lines 140b may include a first end portion, on the upper surface of the deformation plate 120, and a second end portion on the lower surface 120P_L of the protrusion 120P. The first end portion of each of the plurality of vacuum lines 140b may include a single line, and the second end portion of each of the plurality of vacuum lines 140b may include a plurality of lines.

In some implementations, in a plan view, the second end portion of each of the plurality of vacuum lines 140b may have a shape in which portions of a plurality of square rings are combined to one another. For example, an area of the second end portion of each of the plurality of vacuum lines 140b may be greater than an area of the first end portion of the plurality of vacuum lines 140b.

A negative pressure formed at the second end portion of each of the plurality of vacuum lines 140b may be finely adjusted due to the plurality of vacuum lines 140b having the form of branching out into another plurality of lines, therefore, in a process where the collet 100b adsorbs the first semiconductor chip C (see FIG. 14A), the occurrence of cracks in the first semiconductor chip may be inhibited.

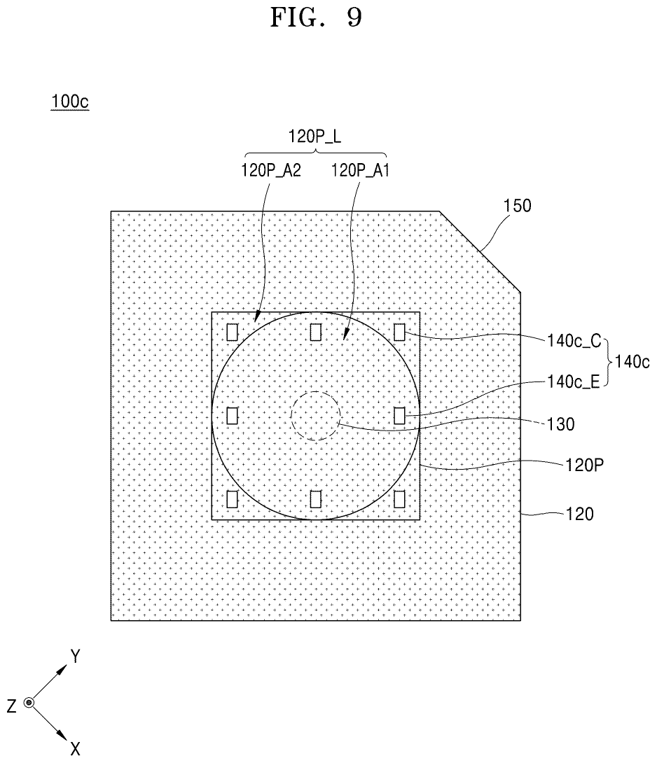

FIG. 9 is a plan view schematically illustrating a collet 100c according to an implementation.

Most of components included in the collet 100c or materials included in the components, which will be described below, are substantially identical or similar to the components or materials described above. Therefore, for convenience of description, differences between the collet 100c in FIG. 9 and the collet 100 in FIG. 2 described above will be mainly described.

Referring to FIG. 9 with FIG. 3, the collet 100c may include the metal plate 110 and the deformation plate 120. The deformation plate 120 may further include the protrusion 120P protruding outward from the lower surface of the deformation plate 120. The lower surface 120P_L of the protrusion 120P of the deformation plate 120 may be divided into the first area 120P_A1 and the second area 120P_A2, where the first area 120P_A1 includes a curved surface being convex outward and the second area 120P_A2 includes a plane surrounding the first area 120P_A1. A distance H1 in the vertical direction (the Z direction) between the lowermost end 120P_A1_L (see FIG. 4) of the lower surface 120P_L of the protrusion 120P of the deformation plate 120 and the uppermost end 120P_A1_U (see FIG. 4) may be about 30 μm to about 80 μm.

The collet 100cmay include the aperture 130 and a plurality of vacuum lines 140c separate from the aperture 130. The aperture 130 may penetrate the metal plate 110, and each of the plurality of vacuum lines 140c may penetrate the metal plate 110 and the deformation plate 120. The aperture 130 and the plurality of vacuum lines 140c may overlap the protrusion 120P of the deformation plate 120 in the vertical direction (the Z direction). The aperture 130 may overlap the first area 120P_A1 of the lower surface 120P_L of the protrusion 120P of the deformation plate 120 in the vertical direction.

In some implementations, the plurality of vacuum lines 140c may include an edge vacuum line 140c_E and a corner vacuum line 140c_C. For example, the edge vacuum line 140c_E may overlap the first area 120P_A1 of the lower surface 120P_L of the protrusion 120P of the deformation plate 120 in the vertical direction (the Z direction), and the corner vacuum line 140c_C may overlap the second area 120P_A2 of the lower surface 120P_L of the protrusion 120P of the deformation plate 120 in the vertical direction (the Z direction). For example, the edge vacuum line 140c_E may be adjacent to an edge of the lower surface 120P_L of the protrusion 120P of the deformation plate 120, and the corner vacuum line 140c_C may be adjacent to the vertex of the lower surface 120P_L of the protrusion 120P of the deformation plate 120.

In some implementations, the length of the aperture 130 in the vertical direction (the Z direction) may be greater than a length of each of the plurality of vacuum lines 140c. In some implementations, a length of the corner vacuum line 140c_C in the vertical direction (the Z direction) may be less than a length of the edge vacuum line 140c_E in the vertical direction (the Z direction). For example, the edge vacuum line 140c_C is on the first area 120P_A1 of the lower surface of the protrusion 120P, which is convex outward, thus may have a relatively greater length in the vertical direction (the Z direction).

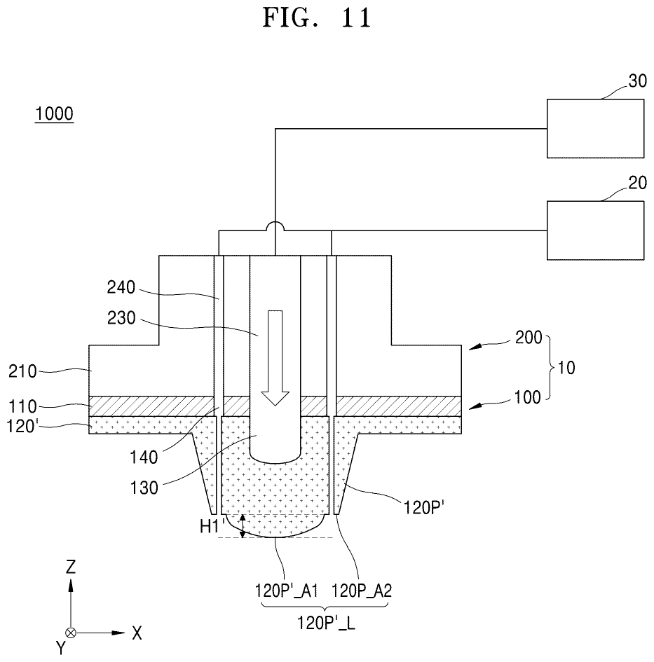

FIGS. 10 and 11 are configuration diagrams schematically illustrating the semiconductor chip bonding apparatus 1000 according to an implementation. More particularly, FIG. 10 illustrates a state in which a pressurizer 30 of the semiconductor chip bonding apparatus 1000 is stopped, and FIG. 11 illustrates a state in which the pressurizer 30 of the semiconductor chip bonding apparatus is in operation.

Referring to FIGS. 10 and 11, the semiconductor chip bonding apparatus 1000 may include the bonding head 10, a vacuum pump 20, and the pressurizer 30. The vacuum pump 20 and the pressurizer 30 may each be connected to the bonding head 10.

The bonding head 10 may include the head body 200 and the collet 100. The collet 100 may include the metal plate 110, which is attached to the head body 200, and the deformation plate 120 apart from the head body 200 with the metal plate 110 therebetween. The collet 100 may further include an aperture 130 and a plurality of vacuum lines 140. The collet 100 may include at least one of the collet 100, the collet 100a, the collet 100b, and the collet 100c described above.

The head body 200 may be configured such that the vacuum pump 20 and the pressurizer 30 are connected to the head body 200. The head body 200 may include a frame 210, and may further include a plurality of first through-holes 240 and a second through-hole 230 penetrating the frame 210.

The second through-hole 230 of the head body 200 may communicate with the aperture 130 of the collet 100, and the plurality of first through-holes 240 of the head body 200 may respectively communicate with the plurality of vacuum lines 140 of the collet 100. The vacuum pump 20 may be connected to the plurality of first through-holes 240 of the head body 200, and the pressurizer 30 may be connected to the second through-hole 230 of the head body 200.

For example, the second through-hole 230 of the head body 200 may provide a path for movement of fluid between the pressurizer 30 and the aperture 130 of the collet 100. The plurality of first through-holes 240 of the head body 200 may provide a path for movement of fluid between the vacuum pump 20 and the plurality of vacuum lines 140 of the collet 100.

The vacuum pump 20 may be connected to the plurality of vacuum lines 140 of the collet 100 through the plurality of first through-holes 240 of the head body 200. Accordingly, the vacuum pump 20 may form a negative pressure in the plurality of vacuum lines 140. For example, when the vacuum pump 20 is in operation, the vacuum pump 20 may reduce a pressure in the plurality of vacuum lines 140 by absorbing air in the plurality of vacuum lines 140.

In some implementations, when the vacuum pump 20 is in operation, the negative pressure may be formed in the plurality of vacuum lines 140, and thus, the first semiconductor chip C (see FIG. 14) below the collet 100 may be attached onto the first area 120P_A1 of the lower surface 120P_L of the protrusion 120P of the collet 100. When the vacuum pump 20 is stopped, the negative pressure formed in the plurality of vacuum lines 140 may be removed, and therefore, the first semiconductor chip C (see FIG. 14A) attached onto the lower surface 120P_L of the protrusion 120P of the deformation plate 120 of the collet 100 may be separated from the collet 100.

The pressurizer 30 may include an air blower configured to discharge air. The pressurizer 30 may be connected to the aperture 130 of the collet 100 through the second through-hole 230 of the head body 200. Accordingly, the pressurizer 30 may apply a pressure to the aperture 130 of the collet 100. For example, when the pressurizer 30 is in operation, the pressurizer 30 may increase the pressure in the aperture 130 by injecting air into the aperture 130.

In some implementations, when the pressurizer 30 is in operation, the air discharged from the pressurizer 30 applies a pressure to the aperture 130, and accordingly, the deformation plate 120 may be deformed due to the pressure. For example, as the deformation plate 120 includes an elastic material, upon receiving an external force, the deformation plate 120 may be deformed depending on the external force. For example, as the pressurizer 30 applies a greater pressure to the aperture 130, the degree of deformation of the deformation plate 120 may be higher. In the present specification, when the pressurizer 30 is in operation, the deformation plate 120 will be referred to as a deformed deformation plate 120′.

For example, as the air discharged from the pressurizer 30 directly hits a bottom surface of the aperture 130 of the collet 100, the bottom surface of the aperture 130 of the collet 100 may be recessed downward in the vertical direction (the Z direction), and a first area 120P'_A1 of a lower surface 120P′_L of a protrusion 120P′ of the deformed deformation plate 120′of the collet 100 may further protrude downward.

In some implementations, an area of the first area 120P′_A1 of the protrusion 120P′ of the deformed deformation plate 120′may be greater than an area of the first area 120P_A1 of the protrusion 120P of the deformation plate 120.

In some implementations, a curvature of the first area 120P′_A1 of the lower surface 120P′_L of the protrusion 120P′ of the deformed deformation plate 120′may be different from the curvature of the first area 120P_A1 of the lower surface 120P_L of the protrusion 120P of the deformation plate 120. For example, when the pressurizer 30 does not apply a pressure to the aperture 130 (e.g., when the aperture of the collet is unpressurized), when the curvature of the first area 120P_A1 of the lower surface 120P_L of the protrusion 120P of the deformation plate 120 is a first curvature and the pressurizer 30 applies a pressure to the aperture 130, the curvature of the first area 120P′_A1 of the lower surface 120P′_L of the protrusion 120P′ of the deformed deformation plate 120′may be a second curvature greater than the first curvature.

For example, when the deformation plate 120 is deformed by the pressurizer 30, a distance H1′ in the vertical direction (the Z direction) between an uppermost end and a lowermost end of the first area 120P′_A1 of the lower surface 120P′_L of the protrusion 120P′ of the deformed deformation plate 120′may increase. For example, the distance H1′in the vertical direction (the Z direction) between the uppermost end and the lowermost end of the first area 120P′_A1 of the lower surface 120P′_L of the protrusion 120P′ of the deformed deformation plate 120′may be about 90 μm to about 150 μm.

For example, when the pressurizer 30 is stopped, the distance H1 in the vertical direction (the Z direction) between the uppermost end and the lowermost end of the first area 120P_A1 of the lower surface 120P_L of the protrusion 120P of the deformation plate 120 may be a first distance. When the pressurizer 30 is in operation, the distance H1′ in the vertical direction (the Z direction) between the uppermost end and the lowermost end of the first area 120P′_A1 of the lower surface 120P′_L of the protrusion 120P′ of the deformed deformation plate 120′may be a second distance greater than the first distance. For example, the second distance may be greater about 10 μm to about 120 μm than the first distance.

In some implementations, when the vacuum pump 20 is in operation, the pressurizer 30 may operate. For example, when the vacuum pump 20 generates the negative pressure in the plurality of vacuum lines 140 and the first semiconductor chip C (see FIG. 14A) is attached to the collet 100, the pressurizer 30 may deform the deformation plate 120 of the collet 100 by applying the pressure to the aperture 130. As the pressurizer 30 is in operation and the lower surface 120P_L of the protrusion 120P of the deformation plate 120 is deformed, the first semiconductor chip C (see FIG. 14A) may also be deformed according to the shape of the lower surface 120P′_L of the protrusion 120P′ of the deformed deformation plate 120′.

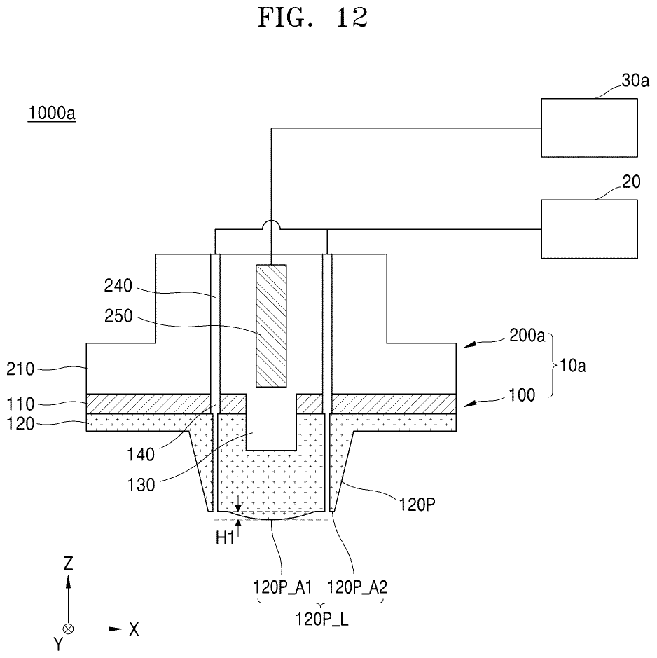

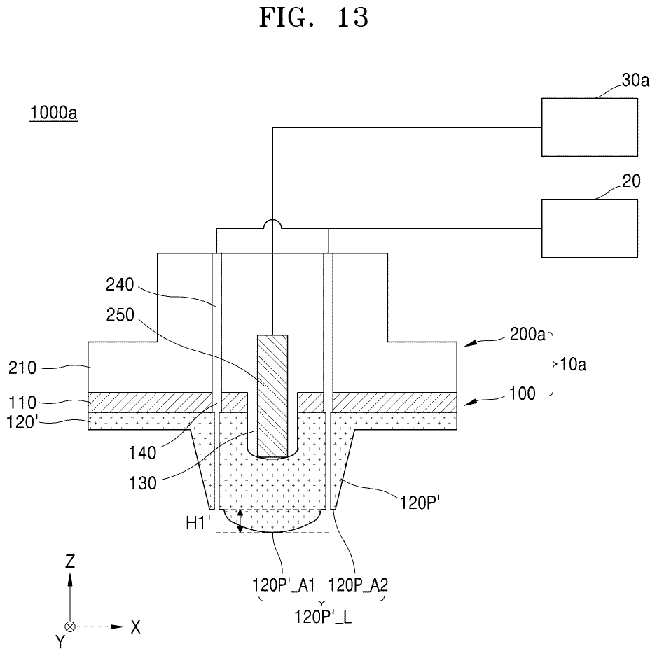

FIGS. 12 and 13 are configuration diagrams schematically illustrating a semiconductor chip bonding apparatus 1000a according to an implementation. More particularly, FIG. 12 illustrates that a pressurizer 30a of the semiconductor chip bonding apparatus 1000a is stopped, and FIG. 13 illustrates that the pressurizer 30a of the semiconductor chip bonding apparatus 1000a is in operation.

Most of components included in the semiconductor chip bonding apparatus 1000a or materials included in the components, which will be described below, are substantially identical or similar to the components or materials described above. Therefore, for convenience of description, differences between the semiconductor chip bonding apparatus 1000a in FIG. 12 and the semiconductor chip bonding apparatus 1000 in FIG. 10 described above will be mainly described.

The semiconductor chip bonding apparatus 1000a may include a bonding head 10a including a head body 200a and the collet 100, the vacuum pump 20 connected to the bonding head 10a, and the pressurizer 30a connected to the bonding head 10a.

The collet 100 may be detachably attached to a lower surface of the head body 200a. For example, the collet 100 attached to the head body 200a may be changed according to bonding environments. The semiconductor chip bonding apparatus 1000a may further include a driver configured to move the head body 200a. For example, the head body 200a may move in the first horizontal direction (the X direction), the second horizontal direction (the Y direction), and the vertical direction (the Z direction). For example, as the head body 200a is moved, the collet 100 attached to the head body 200a may be moved along the head body 200a.

The collet 100 may include the metal plate 110, which is attached to the head body 200a, and the deformation plate 120 under the metal plate 110. The collet 100 may further include the aperture 130 and the plurality of vacuum lines 140. The collet 100 may include at least one of the collet 100, the collet 100a, the collet 100b, and the collet 100c described above.

For example, the deformation plate 120 of the collet 100 may further include the protrusion 120P protruding downward in the vertical direction (the Z direction), and the lower surface 120P_L of the protrusion 120P of the protrusion 120P may further include the first area 120P_A1 that is a curved surface being convex outward. In some implementations, the lower surface 120P_L of the protrusion 120P may be divided into the first area 120P_A1 and the second area 120P_A2 that is a plane surrounding the first area 120P_A1.

For example, the aperture 130 and the plurality of vacuum lines 140 of the collet 100 may overlap the protrusion 120P of the deformation plate 120 of the collet 100 in the vertical direction (the Z direction). The aperture 130 may overlap the first area 120P_A1 of the lower surface 120P_L of the protrusion 120P of the deformation plate 120 in the vertical direction (the Z direction), and each of the plurality of vacuum lines 140 may overlap the second area 120P_A2 of the lower surface 120P_L of the protrusion 120P of the deformation plate 120 in the vertical direction (the Z direction).

The head body 200a may include the frame 210, the plurality of first through-holes 240 penetrating the frame 210, and a pressurizing pin 250 in the frame 210.

The plurality of first through-holes 240 may respectively communicate with the plurality of vacuum lines 140 of the collet 100. The vacuum pump 20 may be connected to the plurality of first through-holes 240. The plurality of first through-holes 240 of the head body 200 may provide a path for movement of fluid between the vacuum pump 20 and the plurality of vacuum lines 140 of the collet 100.

The vacuum pump 20 may be connected to the plurality of vacuum lines 140 of the collet 100 through the plurality of first through-holes 240 of the head body 200. Accordingly, when the vacuum pump is in operation, the vacuum pump may reduce the pressure in the plurality of vacuum lines 140 by absorbing the air in the plurality of vacuum lines 140.

The pressurizing pin 250 of the head body 200a may be above the aperture 130 of the collet 100. The pressurizing pin 250 may be in the frame 210 of the head body 200a, such that the pressurizing pin 250 may be moved in the vertical direction (the Z direction). The pressurizer 30a may be configured to move the pressurizing pin 250. For example, the pressurizer 30a may include an actuator. For example, the pressurizer 30a may move the pressurizing pin 250 the vertical direction (the Z direction), to thereby allow the pressurizing pin 250 to apply a pressure to the aperture 130. For example, the pressurizing pin 250 may move downward in the vertical direction (the Z direction) by the pressurizer 30a and push a bottom of the aperture 130.

In some implementations, a state in which the pressurizer 30a is in operation may indicate a state where the pressurizer 30a moves the pressurizing pin 250 downward in the vertical direction (the Z direction) and the pressurizing pin 250 pushes the bottom of the aperture 130. In some implementations, a state in which the pressurizer 30a is stopped may indicate a state where a position of the pressurizing pin 250 is set such that the pressurizing pin 250 is apart from the bottom of the aperture 130.

In some implementations, when the pressurizer 30a is in operation, the pressurizer 30a may apply a pressure to the aperture 130 through the pressurizing pin 250. When the pressurizer 30a applies the pressure to the aperture 130, as the bottom of the aperture 130 becomes a curved surface recessed downward, the curvature of the first area 120P_A1 of the lower surface 120P_L of the protrusion 120P of the deformation plate 120 may increase. In some implementations, when the pressurizer 30a is changed from the state of being in operation to the state of being stopped, the deformed deformation plate 120′may be recovered to the deformation plate 120 as it used to be.

As the pressurizer 30a pushes the pressurizing pin 250 downward in the vertical direction (the Z direction), the deformation plate 120 may be deformed. For example, the deformation plate 120, which is in a state where the pressurizer 30a pushes the aperture 130 by using the pressurizing pin 250, may be referred to as the deformed deformation plate 120′. That is, a state of the deformation plate 120, when the pressurizer 30a is in operation, may be referred as the deformed deformation plate 120′.

In some implementations, the curvature of the first area 120P′_A1 of the lower surface 120P′_L of the protrusion 120P′ of the deformed deformation plate 120′may be greater than the curvature of the first area 120P_A1 of the lower surface 120P_L of the protrusion 120P of the deformation plate 120 in the initial state.

In some implementations, the distance H1′ in the vertical direction (the Z direction) between the uppermost end and the lowermost end of the first area 120P′_A1 of the lower surface 120P′_L of the protrusion 120P′ of the deformed deformation plate 120′may be about 90 μm to about 150 μm. In some implementations, the distance H1 in the vertical direction (the Z direction) between the uppermost end and the lower most end of the first area 120P_A1 of the lower surface 120P_L of the protrusion 120P of the deformation plate 120 in the initial state may be about 30 μm to about 80 μm.

For example, when an external force is applied to the aperture 130 by the pressurizer 30a, a degree by which the first area 120P_A1 of the lower surface 120P_L of the protrusion 120P of the deformation plate 120 may increase. For example, compared with the distance H1 in the vertical direction (the Z direction) between the uppermost end and the lowermost end of the first area 120P_A1 of the lower surface 120P_L of the protrusion 120P of the deformation plate 120 in the initial state, the distance H1′ in the vertical direction (the Z direction) between the uppermost end and the lowermost end of the first area 120P′_A1 of the lower surface 120P′_L of the protrusion 120P′ of the deformed deformation plate 120′may be greater about 10 μm to about 120 μm.

FIGS. 14A to 14F are configuration diagrams sequentially illustrating processes of bonding semiconductor chips by using the semiconductor chip bonding apparatus 1000, according to an implementation. FIGS. 14A to 14F illustrate attaching the first semiconductor chip C onto the second semiconductor chip B.

For example, the first semiconductor chip C and the second semiconductor chip B may each include a portion of a High Bandwidth Memory (HBM). The attaching of the first semiconductor chip C onto the second semiconductor chip B may be a part of a process of manufacturing the HBM. In some implementations, the second semiconductor chip B may be named as a HBM controller die or a buffer chip, and the first semiconductor chip may be named as a Dynamic Random Access Memory (DRAM) die or a core chip.

In some implementations, each of the first semiconductor chip C and the second semiconductor chip B may include a semiconductor device including various types of individual devices. The individual devices of the first semiconductor chip C and the second semiconductor chip B may include various types of microelectronic devices, e.g., metal-oxide-semiconductor field effect transistors (MOSFET) such as a complementary metal-oxide-semiconductor (CMOS) transistor, a system large scale integration (LSI), image sensors such as a CMOS imaging sensor (CIS), a micro-electro-mechanical system (MEMS), an active element, a passive element, and the like.

In some implementations, the individual devices in each of the first semiconductor chip C and the second semiconductor chip B may include a memory cell. For example, the memory cell may include a nonvolatile memory cell, e.g., flash memory, Phase-change Random Access Memory (PRAM), Magnetoresistive Random Access Memory (MRAM), Ferroelectric Random Access Memory (FeRAM), or Resistive Random Access Memory (RRAM). In some implementations, the memory cell may include a volatile memory cell such as Dynamic Random Access Memory (DRAM) or Static Random Access Memory (SRAM).

Referring to FIG. 14A, the semiconductor chip bonding apparatus 1000 may adsorb the first semiconductor chip C. For example, the semiconductor chip bonding apparatus 1000 may pick up any one of a plurality of the first semiconductor chips C on a carrier substrate 2000. However, the implementation is not limited thereto, and the semiconductor chip bonding apparatus 1000 may pick up one of the plurality of first semiconductor chips C on a dicing tape.

The collet 100 of the bonding head 10 of the semiconductor chip bonding apparatus 1000 may include the deformation plate 120 including the protrusion 120P at the lower surface. The first semiconductor chip C may be attached onto the lower surface 120P_L of the protrusion 120P of the deformation plate 120 of the collet 100. For example, after placing the bonding head 10 on the first semiconductor chip C, by generating the negative pressure in the plurality of vacuum lines 140 of the collet 100 of the bonding head 10, by using the vacuum pump 20, the first semiconductor chip C may be attached onto the lower surface 120P_L of the protrusion 120P of the deformation plate 120 of the collet 100.

For example, the lower surface 120P_L of the protrusion 120P of the deformation plate 120 of the collet 100 may include a curved surface being convex outward. For example, the first semiconductor chip C may be deformed depending on a shape of the lower surface 120P_L of the protrusion 120P of the deformation plate 120 of the collet 100. The first semiconductor chip C may be curved to have a curvature in correspondence to a curvature of the lower surface 120P_L of the protrusion 120P of the deformation plate 120 of the collet 100. Hereinafter, the first semiconductor chip C, which is attached to the collet 100 and curved, may be referred to as a pickup first semiconductor chip CC.

Referring to FIGS. 14B and 14C, the semiconductor chip bonding apparatus 1000 may move the pickup first semiconductor chip CC onto the second semiconductor chip B and deform the deformation plate 120.

The semiconductor chip bonding apparatus 1000 may maintain the vacuum pump 20 to be in the operation and drive the pressurizer 30 to operate. When the pressurizer 30 is in operation, the deformation plate 120 may be the deformed deformation plate 120′that is in a deformed state.

A curvature of the first area of the lower surface 120P′_L of the protrusion 120P′ of the deformed deformation plate 120′may be greater than a curvature of the first area of the lower surface 120P_L of the protrusion 120P of the deformation plate 120 in the initial state. For example, a height difference in the first area of the lower surface 120P′_L of the protrusion 120P′ of the deformed deformation plate 120′may be greater than a height difference in the first area of the lower surface 120P_L of the protrusion 120P of the deformation plate 120 in the initial state. The height difference in the first area may indicate a distance in the vertical direction (the Z direction) between the uppermost end of the first area and the lowermost end of the first area.

When the pressurizer 30 applies the pressure to the aperture 130 of the deformation plate 120 and the deformation plate 120 turns into the deformed deformation plate 120′, the pickup first semiconductor chip CC may also be deformed in correspondence to the shape of the deformed deformation plate 120′. For example, the pickup first semiconductor chip CC deformed due to the deformed deformation plate 120′may be referred to as a deformed pickup first semiconductor chip CC′.

The deformed pickup first semiconductor chip CC′ may be bent by a greater degree than the pickup first semiconductor chip CC. For example, the degree by which the deformed pickup first semiconductor chip CC′ is bent may correspond to the degree of deformation of the first area of the lower surface 120P′_L of the protrusion 120P′ of the deformed deformation plate 120′.

Referring to FIGS. 14D to 14F, the semiconductor chip bonding apparatus 1000, after placing the deformed pickup first semiconductor chip CC′ on the second semiconductor chip B, may stop the vacuum pump 20 and the pressurizer 30, and may apply a pressure between the first semiconductor chip C and the second semiconductor chip B, to thereby attach the first semiconductor chip C onto the second semiconductor chip B.

The pressurizer 30 and the vacuum pump 20, while continuously being in operation, may move the bonding head 10 such that the deformed pickup first semiconductor chip CC′ is on the second semiconductor chip B. Next, by stopping the pressurizer 30, the deformed deformation plate 120′may be returned to the deformation plate 120 in the initial state. As the deformed deformation plate 120′returns to the deformation plate 120 in the initial state, the deformed pickup first semiconductor chip CC′ may also return to the pickup first semiconductor chip CC.

As the deformed pickup first semiconductor chip CC′ is recovered to the pickup first semiconductor chip CC, an area in which the second semiconductor chip B and the pickup first semiconductor chip CC contact each other may gradually increase. For example, as the degree by which the deformed pickup first semiconductor chip CC′ is bent gradually decreases, an area in which the second semiconductor chip B and the deformed pickup first semiconductor chip CC′ may gradually increase from a center to the deformed pickup first semiconductor chip CC′ to a boundary of the deformed pickup first semiconductor chip CC′.

Next, by stopping the vacuum pump 20, the negative pressure formed in the plurality of vacuum lines 140 of the collet 100 may be removed. By doing so, the pickup first semiconductor chip CC attached under the collet 100 may be separated from the collet 100 and recovered to the first semiconductor chip C having the form of a flat plate.

For example, in a process of sequentially stopping the pressurizer 30 and the vacuum pump 20, the bonding head 10 may move downward in the vertical direction (the Z direction) to continuously apply a pressure onto an upper surface of the second semiconductor chip B.

Through the aperture 130 and the pressurizer 30 of the collet 100, the deformation plate 120 of the collet may be continuously changed, and by attaching the first semiconductor chip C onto the second semiconductor chip B, and by doing so, in an edge area of the first semiconductor chip C, the reliability of combination between the first semiconductor chip C and the second semiconductor chip B may be improved.

As the first area of the lower surface 120P_L of the protrusion 120P is under the aperture 130 of the collet 100, the deformation plate 120, from which a portion is removed by the aperture 130 and which is structurally weakened, may be complemented. Accordingly, after stopping the vacuum pump 20 and the pressurizer 30, while the bonding head 10 applies the pressure between the first semiconductor chip C and the second semiconductor chip B, the reliability of bonding between the first semiconductor chip C and the second semiconductor chip B may be improved in an area of the first semiconductor chip C under the aperture 130 of the collet 100, e.g., the center area of the first semiconductor chip C.

Although the present disclosure has been described above with reference to the accompanying drawings, the descriptions are only to provide implementations, and it would be understood to those skilled in the art that various modifications and other equivalents may be made therefrom. Accordingly, the technical scope of the present disclosure will be defined by the following claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A bonding head comprising:
a head body; and
a collet detachably attached to a lower surface of the head body, the collet comprising a metal plate and a deformation plate on a lower surface of the metal plate,
wherein the collet defines an aperture and a plurality of vacuum lines, the aperture extends through the metal plate and a portion of the deformation plate, and the plurality of vacuum lines extend through the metal plate and the deformation plate,
wherein the deformation plate comprises a protrusion that protrudes in a vertical direction from a lower surface of the deformation plate, and
wherein a lower surface of the protrusion comprises a first area that has a curved surface with a convex shape.

2. The bonding head of claim 1, wherein
a distance in the vertical direction between an uppermost end and a lowermost end of the first area of the lower surface of the protrusion is 30 μm to 80 μm.

3. The bonding head of claim 1, wherein the aperture of the collet vertically overlaps a lowermost end of the first area of the lower surface of the protrusion.

4. The bonding head of claim 1, wherein a curvature of the first area of the lower surface of the protrusion is 0.002 mm⁻¹ to 0.005 mm⁻¹.

5. The bonding head of claim 1, wherein
an elastic modulus of the deformation plate is 3 MPa to 5 MPa, and
an elastic modulus of the metal plate is greater than the elastic modulus of the deformation plate.

6. The bonding head of claim 1, wherein
the lower surface of the protrusion comprises the first area and a second area surrounding the first area, and
the second area of the lower surface of the protrusion is at least partially planar.

7. The bonding head of claim 6, wherein
the aperture of the collet vertically overlaps the first area of the lower surface of the protrusion of the collet, and
each of the plurality of vacuum lines of the collet vertically overlaps the second area of the lower surface of the protrusion of the collet.

8. The bonding head of claim 6,
wherein the plurality of vacuum lines comprise an edge vacuum line and a corner vacuum line, and
wherein the edge vacuum line vertically overlaps the first area of the protrusion of the collet, and the corner vacuum line vertically overlaps the second area of the protrusion of the collet.

9. The bonding head of claim 1, wherein,
the lower surface of the protrusion has a square shape in a plane perpendicular to the vertical direction, and
the first area of the lower surface of protrusion has a circular shape in the plane, a diameter of the first area being equal to a width of the lower surface.

10. The bonding head of claim 1, wherein
each of the plurality of vacuum lines of the collet has an end portion adjacent to the lower surface of the protrusion of the deformation plate, and the end portion comprises a plurality of lines arranged along a lateral direction perpendicular to the vertical direction.

11. A semiconductor chip bonding apparatus comprising:
a bonding head comprising a head body and a collet, wherein the collet is attached to a lower surface of the head body, and the collet comprises a metal plate and a deformation plate;
a vacuum pump connected to the head body of the bonding head; and
a pressurizer connected to the head body of the bonding head,
wherein the collet of the bonding head defines:
an aperture extending through the metal plate and a portion of the deformation plate; and
a plurality of vacuum lines extending through the metal plate and the deformation plate,
wherein the deformation plate of the collet comprises a protrusion that protrudes in a vertical direction from a lower surface of the deformation plate,
wherein a lower surface of the protrusion of the deformation plate comprises a first area that has a curved surface with a convex shape, and
wherein the aperture of the collet and each of the plurality of vacuum lines of the collet vertically overlap the protrusion of the deformation plate of the collet.

12. The semiconductor chip bonding apparatus of claim 11, wherein
the vacuum pump is connected to the plurality of vacuum lines of the collet through the head body, and the vacuum pump is configured to generate a negative pressure in the plurality of vacuum lines of the collet.

13. The semiconductor chip bonding apparatus of claim 11, wherein
the head body of the bonding head comprises a pressurizing pin configured to be inserted into the aperture of the collet, and
the pressurizer is configured to move the pressurizing pin of the head body to enable the pressurizing pin to push a bottom of the aperture of the collet.

14. The semiconductor chip bonding apparatus of claim 11, wherein
the pressurizer comprises an air blower, the pressurizer is connected to the aperture of the collet through the head body, and the pressurizer is configured to apply pressure to the aperture of the collet.

15. The semiconductor chip bonding apparatus of claim 11, wherein,
based on the aperture of the collet being unpressurized, a distance in the vertical direction between an uppermost end and a lowermost end of the first area of the lower surface of the protrusion of the deformation plate is 30 μm to 80 μm.

16. The semiconductor chip bonding apparatus of claim 11, wherein,
based on the aperture of the collet being unpressurized, the first area of the lower surface of the protrusion of the deformation plate has a first curvature, and
based on the pressurizer applying pressure to the aperture of the collet, the first area of the lower surface of the protrusion of the deformation plate has a second curvature that is greater than the first curvature.

17. The semiconductor chip bonding apparatus of claim 16, wherein,
based on the pressurizer applying pressure to the aperture of the collet, a distance in the vertical direction between an uppermost end and a lowermost end of the first area of the lower surface of the protrusion of the deformation plate is 90 μm to 150 μm.

18. The semiconductor chip bonding apparatus of claim 16, wherein the pressurizer is configured to apply the pressure to the aperture of the collet based on the vacuum pump generating negative pressure in the plurality of vacuum lines.

19. A semiconductor chip bonding apparatus comprising:
a bonding head comprising a head body and a collet, wherein the head body comprises a plurality of first through-holes and a second through-hole, the collet is attached to a lower surface of the head body, and the collet comprises a metal plate and a deformation plate;
a vacuum pump connected to the plurality of first through-holes; and
an air blower connected to the second through-hole,
wherein the collet of the bonding head defines:
an aperture connected to the second through-hole, the aperture extending through the metal plate and at least a portion of the deformation plate; and
a plurality of vacuum lines respectively connected to the plurality of first through-holes, the plurality of vacuum lines extending through the metal plate and the deformation plate,
wherein the deformation plate comprises a protrusion that protrudes in a vertical direction from a lower surface of the deformation plate,
wherein a lower surface of the protrusion comprises a first area that has a curved surface with a convex shape, and
wherein the aperture and each of the plurality of vacuum lines vertically overlap the protrusion of the deformation plate of the collet.

20. The semiconductor chip bonding apparatus of claim 19, wherein,
based on the aperture being unpressurized, a distance in the vertical direction between an uppermost end and a lowermost end of the lower surface of the protrusion of the deformation plate of the collet is 30 μm to 80 μm, and
based on the air blower discharging air to the aperture of the collet, the distance in the vertical direction between the uppermost end and the lowermost end of the lower surface of the protrusion of the deformation plate of the collet is 90 μm to 150 μm.
